(19) United States
(12) Patent Application Publication
(10) Pub. No.: US 2005/0287300 A1
(43) Pub. Date: Dec. 29, 2005

(54) Use of new polysiloxanes containing (meth) acrylic ester groups attached via SiOC groups as additives for radiation-curing coatings

(75) Inventors: Sascha Herrwerth, Essen (DE); Pedro Cavaleiro, Viersen (DE); Jutta Esselborn, Essen (DE); Sascha Oestreich, Essen (DE)

Correspondence Address: FROMMER LAWRENCE & HAUG, 745 FIFTH AVENUE- 10TH FL., NEW YORK, NY, 10151, US

(73) Assignee: Goldschmidt AG

(21) Appl. No.: 11/127,642

(22) Filed: May 12, 2005

(30) Foreign Application Priority Data
May 14, 2004 (DE) 10 2004 024 009.4

(51) Int. Cl. C23C 16/00

(52) U.S. Cl. 427/255.5

(57) ABSTRACT

The invention provides for the use of organopolysiloxanes having (meth)acrylic ester groups (R³) attached pendently and terminally or only pendently via SiOC groups, of the general average formula (I) 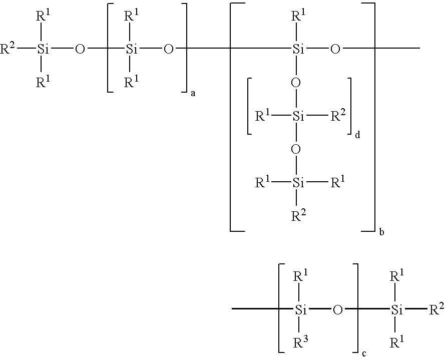 as additives for radiation-curing coatings.

### FIELD OF THE INVENTION

The invention relates to the use of innovative polysiloxanes containing (meth)acrylic ester groups attached via SiOC groups as additives for radiation-curing (UV rays, electron beams) coatings.

### INCORPORATION BY REFERENCE

This application claims benefit of German patent application Serial Nos. DE 103 59 764 filed on May 12, 2004.

The foregoing applications, and all documents cited therein or during their prosecution (“appln cited documents”) and all documents cited or referenced in the appln cited documents, and all documents cited or referenced herein (“herein cited documents”), and all documents cited or referenced in herein cited documents, together with any manufacturer's instructions, descriptions, product specifications, and product sheets for any products mentioned herein or in any document incorporated by reference herein, are hereby incorporated herein by reference, and may be employed in the practice of the invention.

### BACKGROUND OF THE INVENTION

The organopolysiloxanes containing (meth)acrylate groups have excellent properties as additives in radiation-curing coatings, especially printing inks. These coatings possess not only good release properties but also improved scratch resistance and enhanced gliding properties.

Absence of emissions, low capital costs, and lower energy requirement as a result of short drying units, high production rates by virtue of rapid curing, and, in many cases, improved coating quality, especially in terms of gloss and abrasion resistance, are the reasons why radiation curing is the most expansive form of application within the field of industrial coatings.

Radiation-curing coatings are known and are described, for example, in “UV & EB curing formulation for printing inks, coatings & paints” (R. Holman, P. Oldring, London 1988) and “The Formulation of UV-Curable Powder Coatings” (J. Bender, K. Lehmann et al., RadTech Europe 1999, Conference Proceedings, page 615 ff.).

Their properties are causally linked with the underlying oligomers. The majority of the oligomers available commercially that are employed in radiation-curing (UV/EB) systems are based on modified acrylates (Mw=300 to 2000 g/mol).

The epoxy acrylates frequently used for papercoatings in particular are prized for their rapid cure and the achievable hardness and chemical resistance. For high-grade coatings urethane acrylates, too, are used, which result not only in improved flexibility but also, in particular, in excellent wetting behavior and also chemical resistance and hardness.

The use of polyether acrylates, in contrast, makes it easier to achieve a desired, relatively low processing viscosity. Here, however, it is necessary to accept reductions in terms of the abovementioned properties.

Further formula ingredients include one or more photoinitiators, pigment(s), and a functional monomer, frequently a polyfunctional monomer, having a molecular weight Mw of up to 300 g/mol, as reactive diluent, which adapts the viscosity of the system to the processing conditions.

One important field of use besides that of the wood-processing industry is in printing inks for paper, such as are used, for example, for printing record sleeves, book covers, scenic and fine art postcards and high-grade catalogues. In the course of the industrial manufacture of these printed products difficulties are presented by the handling of these articles. For instance, damage to the surface of units stacked after the radiation-induced curing of the ink cannot always be avoided.

In the manufacture of printed packaging materials, moreover, a rapid release action of the printing ink is desirable, so that labels or codes applied shortly after the printing operation can be removed again at a later point in time without damaging the printed image.

Attempts have already been made to improve the handling properties of freshly printed articles by adding friction-reducing additives, such as oils or waxes (e.g., polyethylene waxes or polytetrafluoroethylene waxes), to the printing ink or applying them subsequently to the printed surfaces. In many cases this leads to a disruptive loss of gloss. The subsequent application of wax to the printed product is also unable to give satisfaction in every case, especially since this additional step in the process raises the manufacturing costs. In addition, high concentrations are required in order to achieve an improvement in scratch resistance. A significant release action is not obtained in this way.

As in air-drying systems or those which operate with forced (temperature) drying, silicone oils, or else organically modified siloxanes, such as polyether siloxanes, for example, are also nowadays used for these purposes. These compounds, however, are not incorporated chemically into the film in the course of the radiation-induced crosslinking reaction, and so these additives, owing to their incompatibility, rise to the surface over time, and the silicone can on the one hand—for example, in the case of repeated printing operations—reach places where it has a disruptive effect, and, on the other hand, the effect of improved scratch resistance is at best of a temporary nature. In particular it is not possible entirely to avoid the silicone additive, in the course of stacking operations, reaching the reverse of the overlying printed product.

In the packaging industry it must be ensured, furthermore, that the addition of additive provides the printed product with a release effect in as short a time as possible, so that codes or labels which are adhered can be removed subsequently without damaging the printed product.

In the art there is therefore a need for crosslinkable, modified silicone additives which, at low concentrations, enhance the handling properties of printed articles, especially those printed in long runs, said additives in particular enhancing the scratch resistance of the fresh surfaces, increasing their gliding properties, exhibiting a high release action very rapidly after crosslinking, and, by virtue of their crosslinking, remaining stationary in the film. Such additives should at the same time be substantially independent of the nature and composition of the printing ink to which they are added to enhance the aforementioned properties, and should be capable of universal application. These additives should be effective in minimal quantities and should not impair the performance properties of the printing ink. In particular they should not adversely affect the development of the surface film and the curing of the printing ink. They must, furthermore, have no deleterious effect on the stability of the printing ink and must not impair the leveling properties.

Polysiloxanes which contain acrylic ester groups (acrylate groups) have become established as additives which can be cured under high-energy radiation, for printing inks, for example, and for preparing film-forming binders or for coating materials for plastic, paper, wood and metal surfaces. The curing is accomplished in particular by UV radiation (following the addition of known photoinitiators, such as benzophenone and its derivatives, for example) or by electron beams.

There are many ways in which polysiloxanes can be provided with (meth)acrylic ester groups. To attach organic groups to a siloxane there are in principle two different types of attachment. In the first case a carbon atom is attached directly to a silicon atom (SiC linkage); in the second case a carbon atom is attached via an oxygen atom to the silicon atom (SiOC linkage). SiC linkage generally results from a hydrosilylation reaction.

Organopolysiloxanes in which the organic groups containing acrylic ester are joined to the polysiloxane backbone via Si—C bonds are state of the art. They can be prepared, for example, by subjecting allyl glycidyl ether or another suitable epoxide having an olefinic double bond to addition reaction with a hydrosiloxane and, following the addition reaction, esterifying the epoxide with acrylic acid, a reaction in which the epoxide ring is opened. This procedure is described in U.S. Pat. No. 4,978,726.

Another possibility for preparing (meth)acrylate-modified polysiloxanes with Si—C linkage of the modifying group(s) involves subjecting a hydrosiloxane to addition reaction with an alcohol having an olefinic double bond, allyl alcohol for example, in the presence of a platinum catalyst and then reacting the OH group of said alcohol with acrylic acid or with a mixture of acrylic acid and other saturated or unsaturated acids. This procedure is described for example in U.S. Pat. No. 4,963,438.

Also possible is the preparation of (meth)acrylate-modified polysiloxanes with Si—C linkage of the modified group(s) by means of the addition reaction of an olefinic double bond, allyl polyether for example, with a hydrosiloxane in the presence of a hydrosilylation catalyst, and an enzymatically catalyzed esterification or transesterification using (meth)acrylic esters. This procedure is described for example in U.S. Pat. No. 6,288,129.

Yet another possibility is to attach two or more (meth)acrylate groups per linker to the siloxane backbone. In order to combine maximum crosslinking effectiveness, i.e., a maximum number of reactive groups, with minimum modification density on the siloxane backbone it is desirable to attach more than one (meth)acrylate group per bridging link. Such methods are described for example in U.S. Pat. No. 6,211,322.

All of these (meth)acrylate-modified organosiloxanes synthesized via SiC chemistry, which at present constitute the state of the art, have the disadvantage that they must be prepared in multistage syntheses, with the attendant high costs and also the high technical complexity for their production.

A number of methods are available for forming an SiOC linkage. Conventionally SiOC linkages are formed by reacting a siloxane with an alcohol and with a leaving group (halogen, for example) attached to the silicon atom.

Organopolysiloxanes where the (meth)acrylate-containing organic groups are joined by an Si—O—C bond to the polysiloxane backbone via a halogen leaving group are described in U.S. Pat. No. 4,301,268 and U.S. Pat. No. 4,306,050. Particularly chlorosiloxanes are widespread for this type of reaction.

Chlorosiloxanes, however, are difficult to handle on account of their extreme readiness to react. The use of chlorosiloxanes, moreover, carries with it the disadvantage that the hydrogen chloride formed in the course of the reaction leads to ecological problems and restricts handling to corrosion-resistant plants. Furthermore, in the presence of chlorosiloxanes and alcohols, organic chlorine compounds may be formed, which are undesirable on toxicological grounds.

Additionally it is not simple to achieve quantitative conversion in the reaction of a chlorosiloxane with an alcohol. In many cases it is necessary to use bases, which act as HCl scavengers, in order to obtain good conversions. Using these bases results in the formation of large quantities of salt waste, which in turn cause problems for their removal and disposal on an industrial scale.

The stability of the Si—O—C bond over long periods of time is decisive for the use as additives for radiation-curing coatings. As a consequence there should be no reaction residues or catalyst residues left in the coating that are capable of catalyzing the hydrolysis of the SiOC bond. The methods cited, however, produce acid residues or a salt load which cannot be removed completely from the reaction mixture. Catalytically active amounts remain in the radiation-curing coating, and even after it has been crosslinked may break down the SiOC bond. Moreover, in accordance with the methods cited, only terminally modified organopolysiloxanes are accessible, and hence there is no possibility of synthesizing organosiloxanes modified pendently with (meth)acrylate via SiOC.

Besides the widespread preparation of terminal (α,ω) organopolysiloxanes with chlorosiloxanes and alcohols, U.S. Pat. No. 5,310,842 and U.S. Pat. No. 6,239,303 describe the synthesis of pendently modified organopolysiloxanes via SiOC chemistry and also the dehydrogenative hydrosilylation of long-chain and short-chain alcohols with SiH-siloxanes using Ru compounds or Pt compounds.

This method is only suitable for effecting terminal and pendent dehydrogenative coupling of various alcohols with SiH-siloxanes.

To the skilled worker, however, it is readily apparent that these aforedescribed procedures are not practicable with alcohols containing (meth)acrylic groups, on account of various Pt- or Ru-catalyzed secondary reactions that occur, such as the attachment of the double bond or carbonyl group of the (meth)acrylate groups to the SiH units (Journal of Polymer Science: Part A: Polymer Chemistry, Vol. 29, 1073-1076).

Furthermore, in contradistinction to the state of the art method, the products obtained, such as those starting from chlorosiloxanes, for example, should not be contaminated with hydrochloric acid originating from the substitution reaction, or with chlorides corresponding to their neutralization products, and, accordingly, the SiOC bond of the (meth)acrylate-modified polysiloxanes prepared should be more stable to hydrolysis.

It follows that, according to the published state of the art, there is no available possibility for synthesizing pendently (meth)acrylate-modified organopolysiloxanes via SiOC chemistry with defined structures. The known methods, which lead to terminally (via SiOC) (meth)acrylate-modified organosiloxanes, leave behind catalytic amounts of substances which break down SiOC bonds.

DE-A-103 59 764, unpublished at the priority date of the present specification, discloses a technically simple process which allows the preparation of new, terminal and/or pendent via SiOC chemistry, (meth)acrylate-modified, radiation-curable polysiloxanes without breakdown of the siloxane backbone.

Using a Lewis-acidic catalyst or a mixture of a carboxylic acid and the salt of a carboxylic acid it is possible to couple (meth)acrylate-containing alcohols selectively with terminal and/or pendent SiH-siloxanes without any observation of breakdown of the siloxane backbone. Furthermore, hydrosilylation reactions of the (meth)acrylate groups with SiH groups, involving SiC linkage, do not occur in the manner described in WO-A-02/12386 for olefinic compounds and SiH-siloxanes using catalysts containing boron.

One subject of DE-A-103 59 764 is a process for preparing organopolysiloxanyl (meth)acrylates by reacting polysiloxanes containing SiH groups, of the general average formula (II) 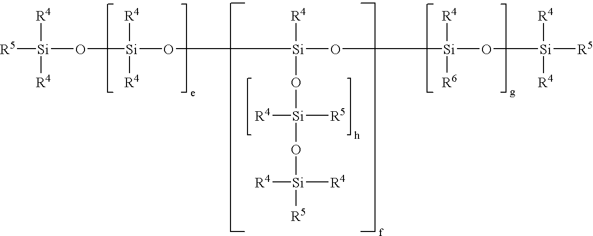
in which
R⁴ radicals are identical or different and selected from linear and branched, saturated, mono- and polyunsaturated alkyl, aryl, alkaryl and aralkyl radicals having 1 to 20 carbon atoms,
R⁵ is H or R⁴,
R⁶ is H,
e is 0 to 1000,
f is 0 to 5,
g is 0 to 200, and
h is 0 to 1000,
at least one radical R⁵ or R⁶ necessarily being H,
   with an alcohol selected from the group consisting of singly and multiply (meth)acrylated monoalcohols and polyalcohols, or of a mixture thereof, or of mixtures of singly or multiply (meth)acrylated monoalcohols or polyalcohols with any desired other alcohols which are selected from the group consisting of linear and branched, saturated, mono- and polyunsaturated, aromatic, aliphatic-aromatic monoalcohols and polyalcohols, polyether monoalcohols, polyether polyalcohols, polyester monoalcohols, polyester polyalcohols, amino alcohols, especially N-alkylamino- and arylamino-EO and —PO alcohols, N-alkylamino and arylamino alcohols, and also mixtures thereof, wherein some or all of the existing SiH groups of the polysiloxane are replaced in one or more process steps, using a Lewis-acidic catalyst or a catalyst composed of a carboxylic acid and salts of carboxylic acids, by alkoxide radicals of the alcohols employed.

A further subject of DE-A-103 59 764 are innovative organopolysiloxanes, having groups which carry (meth)acrylic esters attached pendently and terminally, or only pendently, via SiOC groups, of the general average formula (I) 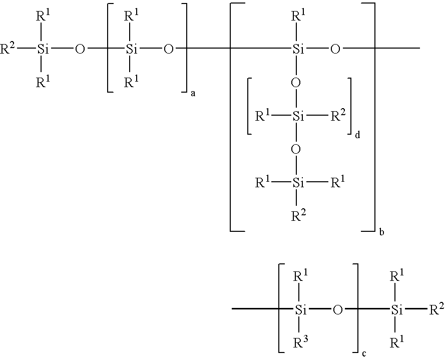
in which
R¹ radicals are identical or different and selected from linear and branched, saturated, mono- and polyunsaturated alkyl, aryl, alkaryl and aralkyl radicals having 1 to 20 carbon atoms,
R² radicals are identical or different radicals R¹ or R³,
R³ radicals are identical or different, singly or multiply (meth)acrylated monoalkoxylates or (meth)acrylated polyalkoxylates, or a mixture thereof, or a mixture of the singly or multiply (meth)acrylated monoalkoxylates or polyalkoxylates with any desired other alkoxylates, selected from the group consisting of linear and branched, saturated, monounsaturated and polyunsaturated, aromatic, aliphatic-aromatic monoalcohols and polyalcohols, polyether monoalcohols, polyether polyalcohols, polyester monoalcohols, polyester polyalcohols, amino alcohols, especially N-alkylamino- and arylamino-ethylene oxide- and -propylene oxide-alcohols, N-alkylamino and arylamino alkoxylates and also mixtures thereof, the ratio of the singly or multiply (meth)acrylated monoalkoxylates or polyalkoxylates to the arbitrary other alkoxylates being chosen such that at least one singly or multiply (meth)acrylated monoalkoxylate or polyalkoxylate radical is present in the organopolysiloxane,
a is 0 to 1000, preferably 0 to 500, especially 0 to 300,
b is 0 to 5,
c is 1 to 200, preferably 2 to 100, especially 3 to 80, and
d is 0 to 1000, preferably 0 to 500, especially 0 to 300,
   at least one of the radicals R² or R³ being a (meth)acrylated monoalkoxylate or polyalkoxylate radical.

It has now been found that these compounds can be used as additives in radiation-curable coatings. They do not have the disadvantages of the additives of the state of the art, and in radiation-curable coatings they produce a considerable improvement in scratch resistance and gliding properties and also in the release behavior.

Citation or identification of any document in this application is not an admission that such document is available as prior art to the present invention.

### SUMMARY OF THE INVENTION

The present invention accordingly provides for the use of organopolysiloxanyl (meth)acrylates obtainable by reacting polysiloxanes containing SiH groups, of the general average formula (II) 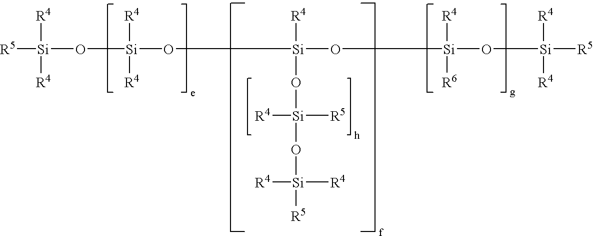
in which
R⁴ radicals are identical or different and selected from linear and branched, saturated, mono- and polyunsaturated alkyl, aryl, alkaryl and aralkyl radicals wherein the alkyl has 1 to 20 carbon atoms, preferably an alkyl radical having 1 to 5 carbon atoms, especially a methyl radical, (NOTE: alkyl has 1 to 20 carbon atoms refers to the number of carbons in the alkyl for alkyl, alkaryl and aralkyl)
R⁵ is H or R⁴,
R⁶ is H,
e is 0 to 1000, preferably 5 to 500, in particular 10 to 300, with particular preference 10 to 200,
f is 0 to 5, preferably <2
g is 0 to 200, and preferably 0 to 100, especially 0 to 80, with particular preference 0 to 50,
h is 0 to 1000, preferably 0 to 500, especially 0 to 300, with particular preference <100,
at least one radical R⁵ or R⁶ necessarily being H,
   with an alcohol selected from the group consisting of singly and multiply (meth)acrylated monoalcohols and polyalcohols, or of a mixture thereof, or of mixtures of singly or multiply (meth)acrylated monoalcohols or polyalcohols with at least one other alcohol selected from the group consisting of linear and branched, saturated, mono- and polyunsaturated, aromatic, aliphatic-aromatic monoalcohols and polyalcohols, polyether monoalcohols, polyether polyalcohols, polyester monoalcohols, polyester polyalcohols, amino alcohols, especially N-alkylamino- and arylamino-EO and —PO alcohols, N-alkylamino and arylamino alcohols, and also mixtures thereof, which comprises replacing some or all of the existing SiH groups of the polysiloxane in one or more process steps, using a Lewis-acidic catalyst or a catalyst composed of a carboxylic acid and salts of carboxylic acids, by alkoxide radicals of the alcohols employed, in amounts of about 0.01% to about 10% by weight, as additives in radiation-curing coatings.

One embodiment of the invention is the use of organopolysiloxanes having groups which carry (meth)acrylic esters attached pendently and terminally or only pendently, via SiOC groups, of the general average formula (I) 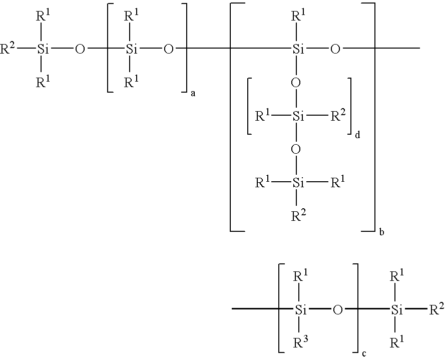
in which
R¹ radicals are identical or different and selected from linear and branched, saturated, mono- and polyunsaturated alkyl, aryl, alkaryl and aralkyl radicals wherein the alkyl has 1 to 20 carbon atoms, preferably an alkyl radical having 1 to 5 carbon atoms, especially the methyl radical, (NOTE: alkyl has 1 to 20 carbon atoms refers to the number of carbons in the alkyl for alkyl, alkaryl and aralkyl)
R² radicals are identical or different radicals R¹ or R³,
R³ radicals are identical or different, singly or multiply (meth)acrylated monoalkoxylates or (meth)acrylated polyalkoxylates, or a mixture thereof, or a mixture of the singly or multiply (meth)acrylated monoalkoxylates or polyalkoxylates with at least one arbitrary other alkoxylate, selected from the group based on linear or branched, saturated, monounsaturated or polyunsaturated, aromatic, aliphatic-aromatic monoalcohols or polyalcohols, polyether monoalcohols, polyether polyalcohols, polyester monoalcohols, polyester polyalcohols, amino alcohols, especially N-alkylamino- or arylamino-ethylene oxide- and -propylene oxide-alcohols, N-alkylamino or arylamino alkoxylates and also mixtures thereof, the ratio of the singly or multiply (meth)acrylated monoalkoxylates or polyalkoxylates to the arbitrary other alkoxylates being chosen such that at least one singly or multiply (meth)acrylated monoalkoxylate or polyalkoxylate radical is present in the organopolysiloxane, preferably at least one compound from the group consisting of 2-hydroxyethyl acrylic acid ester, hydroxypropyl acrylic acid ester, hydroxybutyl acrylic acid ester, monoacrylated polyethers (Bisomer PEA 6), and monoacrylated di- and poly-caprolactones (Sartomer SR 495),
a is 0 to 1000, preferably 5 to 500, especially 10 to 300, with particular preference 10 to 200,
b is 0 to 5, preferably <2,
c is 1 to 200, preferably 1 to 100, especially 1 to 80, with particular preference 1 to 50,
d is 0 to 1000, preferably 0 to 500, especially 0 to 300, with particular preference 0 to 100,
   at least one of the radicals R² or R³ being a (meth)acrylated monoalkoxylate or polyalkoxylate radical, in amounts of 0.01% to 10% by weight, as additives in radiation-curing coatings.

It is noted that in this disclosure and particularly in the claims and/or paragraphs, terms such as “comprises”, “comprised”, “comprising” and the like can have the meaning attributed to it in U.S. Patent law; e.g., they can mean “includes”, “included”, “including”, and the like; and that terms such as “consisting essentially of” and “consists essentially of” have the meaning ascribed to them in U.S. Patent law, e.g., they allow for elements not explicitly recited, but exclude elements that are found in the prior art or that affect a basic or novel characteristic of the invention.

These and other embodiments are disclosed or are apparent from and encompassed by, the following Detailed Description.

### DETAILED DESCRIPTION

The present invention accordingly provides for the use of organopolysiloxanyl (meth)acrylates obtainable by reacting polysiloxanes containing SiH groups, of the general average formula (II) 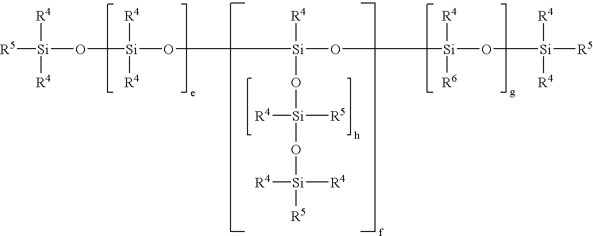
in which
R⁴ radicals are identical or different and selected from linear and branched, saturated, mono- and polyunsaturated alkyl, aryl, alkaryl and aralkyl radicals wherein the alkyl has 1 to 20 carbon atoms, preferably an alkyl radical having 1 to 5 carbon atoms, especially a methyl radical, (NOTE: alkyl has 1 to 20 carbon atoms refers to the number of carbons in the alkyl for alkyl, alkaryl and aralkyl)
R⁵ is H or R⁴,
R⁶ is H,
e is 0 to 1000, preferably 5 to 500, in particular 10 to 300, with particular preference 10 to 200,
f is 0 to 5, preferably <2
g is 0 to 200, and preferably 0 to 100, especially 0 to 80, with particular preference 0 to 50,
h is 0 to 1000, preferably 0 to 500, especially 0 to 300, with particular preference <100,
at least one radical R⁵ or R⁶ necessarily being H,
   with an alcohol selected from the group consisting of singly and multiply (meth)acrylated monoalcohols and polyalcohols, or of a mixture thereof, or of mixtures of singly or multiply (meth)acrylated monoalcohols or polyalcohols with at least one other alcohol selected from the group consisting of linear and branched, saturated, mono- and polyunsaturated, aromatic, aliphatic-aromatic monoalcohols and polyalcohols, polyether monoalcohols, polyether polyalcohols, polyester monoalcohols, polyester polyalcohols, amino alcohols, especially N-alkylamino- and arylamino-EO and —PO alcohols, N-alkylamino and arylamino alcohols, and also mixtures thereof, which comprises replacing some or all of the existing SiH groups of the polysiloxane in one or more process steps, using a Lewis-acidic catalyst or a catalyst composed of a carboxylic acid and salts of carboxylic acids, by alkoxide radicals of the alcohols employed, in amounts of about 0.01% to about 10% by weight, as additives in radiation-curing coatings.

In one embodiment of the invention, wherein when g>0, then e+g is in the range of 20 to 250.

In another embodiment of the invention, the organopolysiloxanyl (meth)acrylates are employed, in amounts of about 0.1% to about 10% by weight, as additives in radiation-curing coatings.

In another embodiment of the invention, the organopolysiloxanyl (meth)acrylates are employed, in amounts of about 0.4% to about 0.6% by weight, as additives in radiation-curing coatings.

One embodiment of the invention is the use of organopolysiloxanes having groups which carry (meth)acrylic esters attached pendently and terminally or only pendently, via SiOC groups, of the general average formula (I) 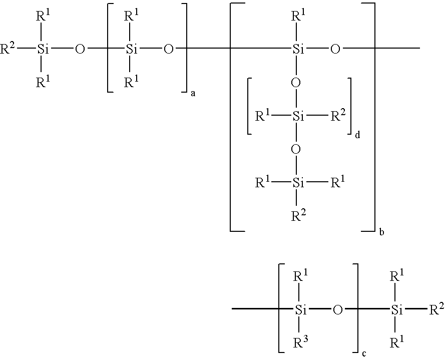
in which
R¹ radicals are identical or different and selected from linear and branched, saturated, mono- and polyunsaturated alkyl, aryl, alkaryl and aralkyl radicals wherein the alkyl has 1 to 20 carbon atoms, preferably an alkyl radical having 1 to 5 carbon atoms, especially the methyl radical, (NOTE: alkyl has 1 to 20 carbon atoms refers to the number of carbons in the alkyl for alkyl, alkaryl and aralkyl)
R² radicals are identical or different radicals R¹ or R³,
R³ radicals are identical or different, singly or multiply (meth)acrylated monoalkoxylates or (meth)acrylated polyalkoxylates, or a mixture thereof, or a mixture of the singly or multiply (meth)acrylated monoalkoxylates or polyalkoxylates with at least one arbitrary other alkoxylate, selected from the group based on linear or branched, saturated, monounsaturated or polyunsaturated, aromatic, aliphatic-aromatic monoalcohols or polyalcohols, polyether monoalcohols, polyether polyalcohols, polyester monoalcohols, polyester polyalcohols, amino alcohols, especially N-alkylamino- or arylamino-ethylene oxide- and -propylene oxide-alcohols, N-alkylamino or arylamino alkoxylates and also mixtures thereof, the ratio of the singly or multiply (meth)acrylated monoalkoxylates or polyalkoxylates to the arbitrary other alkoxylates being chosen such that at least one singly or multiply (meth)acrylated monoalkoxylate or polyalkoxylate radical is present in the organopolysiloxane, preferably at least one compound from the group consisting of 2-hydroxyethyl acrylic acid ester, hydroxypropyl acrylic acid ester, hydroxybutyl acrylic acid ester, monoacrylated polyethers (Bisomer PEA 6), and monoacrylated di- and poly-caprolactones (Sartomer SR 495),
a is 0 to 1000, preferably 5 to 500, especially 10 to 300, with particular preference 10 to 200,
b is 0 to 5, preferably <2,
c is 1 to 200, preferably 1 to 100, especially 1 to 80, with particular preference 1 to 50,
d is 0 to 1000, preferably 0 to 500, especially 0 to 300, with particular preference 0 to 100,
   at least one of the radicals R² or R³ being a (meth)acrylated monoalkoxylate or polyalkoxylate radical, in amounts of about 0.01% to about 10% by weight, as additives in radiation-curing coatings.

In one embodiment of the invention, the a+c is the range from 10 to 250.

In another embodiment of the invention, the organopolysiloxanyl (meth)acrylates are employed, in amounts of about 0.1% to about 10% by weight, as additives in radiation-curing coatings.

In another embodiment of the invention, the organopolysiloxanyl (meth)acrylates are employed, in amounts of about 0.4% to about 0.6% by weight, as additives in radiation-curing coatings.

Preferred effective Lewis-acidic catalysts for the preparation of compounds having not only terminal but also pendent (meth)acrylate radicals are the Lewis-acidic element compounds of main group III, especially element compounds containing boron and/or containing aluminum.

One preferred embodiment envisages using fluorinated and/or nonfluorinated organoboron compounds.

The reactions of the terminal and/or pendent Si—H-functional siloxanes with the above-defined alcohols with boron-containing Lewis acids are carried out in general accordance with the synthesis instructions according to DE-A-103 59 764:

The alcohol is introduced under inert gas, with or without solvent and the boron catalyst, and heated to about 70° C. to about 150° C. Subsequently the Si—H-functional siloxane is added dropwise and the reaction mixture is stirred until reaction is complete. The reaction regime can be modified by introducing the alcohol, the boron catalyst and the Si—H-functional siloxane, with or without solvent, and heating them to reaction temperature (one-pot reaction).

Additionally these reactions can be carried out using inert gas, oxygen-depleted air or inhibitors.

Further effective catalysts, especially for compounds containing terminal and/or pendent (meth)acrylate radicals, are mixtures of at least one acid and at least one salt of an acid, preferably mixtures of at least one organic acid, such as a carboxylic acid, dithiocarboxylic acid, aryl-/alkylsulfonic acid, aryl-/alkylphosphonic acid or aryl-/alkylsulfinic acid, and at least one metal salt or ammonium salt of an organic acid, the metal cation being monovalent or polyvalent. The ratio of salt and acid can be varied within wide ranges, preference being given to a molar ratio of acid to salt in the range from about 1:5 to about 5:1, in particular about 2:3 to about 3:2 mole equivalents. Additionally it is possible to use polyvalent acids or mixtures of monovalent and polyvalent acids and also the corresponding salts with monovalent or polyvalent cations. The pKa of the acid ought not to be negative, since otherwise there is equilibration of the siloxane backbone.

One particularly preferred embodiment of the invention consists in the use of catalytic systems composed of a 1:1 mixture of a carboxylic acid and its metal salt or ammonium salt, the metal being a main group element or transition metal, more preferably a metal from main group 1 or 2. The organic radical of the carboxylic acid is selected from cyclic, linear or branched, saturated, mono- or polyunsaturated alkyl, aryl, alkylaryl or arylalkyl radicals wherein the alkyl has 1 to 40, in particular 1 to 20, carbon atoms.

The reactions of the terminal and/or pendent Si—H-functional siloxanes with the above-defined alcohols with mixtures of at least one acid and at least one salt of an acid are carried out in accordance with the general synthesis instructions of DE-A-103 59 764:

The alcohol is introduced with or without solvent and the catalyst (mixtures of at least one acid and at least one salt of an acid) and heated to about 70° C. to about 150° C. Subsequently the Si—H-functional siloxane is added dropwise and the reaction mixture is stirred until reaction is complete. The reaction regime can be modified by carrying out a one-pot reaction, in which the alcohol, the catalyst and the Si—H-functional siloxane, with or without solvent, are introduced initially.

Individual, or mixtures of, (meth)acrylated polysiloxanes of the invention modified via SiOC chemistry can be mixed in any desired ratio with any desired number of other (meth)acrylated polysiloxanes according to the state of the art.

The compounds, in the form of mixtures if desired, are used in amounts of about 0.01 to about 10% by weight as additives in radiation-curable coatings. In other embodiments of the invention, the amounts range from about 0.1% to about 1% by weight or from about 0.4% to about 0.6% by weight. They do not have the disadvantages of the additives of the state of the art, and in radiation-curable coatings they produce a considerable improvement in the scratch resistance and gliding properties and also in the release behavior.

Scratch resistance is the resistance of a surface to visible damage in the form of lines, caused by hard moving bodies in contact with the surface.

Release force in the context of the present invention is the force required to remove adhesive tape from the a substrate at a speed of 12 mm/s and a peel angle of 180°.

In one embodiment of the invention, the organopolysiloxanyl (meth)acrylates of the invention have at least one of the following properties:

(1) a friction coefficient of about 15 cN to about 60 cN;

(2) a scratch value of about 10 cN to about 20 cN;

(3) a release force after 5 minutes of curing of about 10 cN to about 500 cN;

(4) a release force after 24 hours of curing of about 10 cN to about 500 cN.

The (meth)acrylated polysiloxanes of the invention also are substantially-free of turbidity and/or amine odor resulting in a coating of the coated substrate with similar properties. Substantially-free of turbidity indicates that the (meth)acrylated polysiloxanes appear to be transparent upon inspection by a skilled artisan. Substantially-free of amine odor indicates that the skilled artisan cannot detect an amine odor when using the (meth)acrylated polysiloxanes in coating a substrate.

The (meth)acrylated polysiloxanes of the invention can be compounded in conventional manner with curing initiators, fillers, pigments, other, conventional acrylate systems, and further, customary additives. The compounds can be crosslinked three-dimensionally by means of free radicals and cure thermally with the addition, for example, of peroxides, or under the influence of high-energy radiation, such as UV radiation or electron beams, within a very short time, to form mechanically and chemically robust coats which, given an appropriate composition of the compounds, have predeterminable abhesive properties. If UV light is the radiation source used, then crosslinking takes place preferably in the presence of photoinitiators and/or photosensitizers, such as, for example, benzophenone and its derivatives, or benzoin and corresponding substituted benzoin derivatives.

Photoinitiators and/or photosensitizers are used in the compositions comprising the organopolysiloxanes in amounts preferably of about 0.01% to about 10% by weight, in particular of about 0.1% to about 5% by weight, based in each case on the weight of the acrylate-functional organopolysiloxanes.

### EXAMPLES

### Example 1

Reaction of a pendent and terminal Si—H-functional siloxane (e=166, g=10, R⁵═H) with 2-hydroxyethyl acrylate (CH₂═CH—C(O)—O—CH₂—CH₂—OH) using a boron catalyst:

15.7 g of 2-hydroxyethyl acrylate are heated to 90° C. in an inert atmosphere in a four-necked flask equipped with stirrer, high-efficiency reflux condenser, thermometer and dropping funnel together with 0.053 g of tris(pentafluorophenyl)borane catalyst, 300 ppm of methylhydroquinone and 83.4 g of toluene. When the temperature has been reached, 123.3 g of terminally and pendently Si—H-functionalized polydimethylsiloxane (e=166, g=10, R⁵═H) of the general formula (HMe₂SiO(SiMeHO)₁₀(SiMe₂O)₁₆₆SiMe₂H (SiH value: 0.081%) are added dropwise over the course of 15 minutes. When addition is at an end, and after cooling, the conversion, according to the SiH value method, was 100%.

Distillative removal of the volatile compounds gives a colorless, slightly turbid liquid.

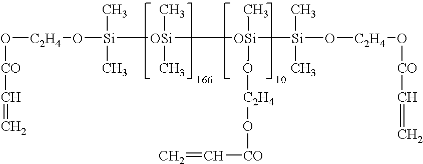

### Example 2

Reaction of a pendent and terminal Si—H-functional siloxane (e=190, g=10, R⁵═H) with hydroxypropyl acrylate (CH₂═CH—C(O)—O—C₃H₆—OH) using a boron catalyst:

16.91 g of hydroxypropyl acrylate are heated to 90° C. in an inert atmosphere in a four-necked flask equipped with stirrer, high-efficiency reflux condenser, thermometer and dropping funnel together with 0.051 g of tris(pentafluorophenyl)borane catalyst, 300 ppm of methylhydroquinone and 30 g of toluene. When the temperature has been reached, 132.6 g of terminally and pendently Si—H-functionalized polydimethylsiloxane (e=190, g=10, R⁵═H) of the general formula HMe₂SiO(SiMeHO)₁₀(SiMe₂O)₁₉₀SiMe₂H (SiH value: 0.076%) are added dropwise over the course of 15 minutes. When addition is at an end, and after cooling, the conversion, according to the SiH value method, was 100%.

Distillative removal of the volatile compounds gives a colorless, clear liquid.

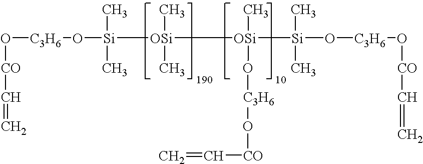

### Example 3

Reaction of a pendent and terminal Si—H-functional siloxane (e=166, g=10, R⁵═H) with 4-hydroxybutyl acrylate (CH₂═CH—C(O)—O—C₄H₈—OH) using a boron catalyst:

151.4 g of 4-hydroxybutyl acrylate are heated to 90° C. in an inert atmosphere in a four-necked flask equipped with stirrer, high-efficiency reflux condenser, thermometer and dropping funnel together with 0.051 g of tris(pentafluorophenyl)borane catalyst, 300 ppm of methylhydroquinone and 259.4 g of toluene. When the temperature has been reached, 1145.3 g of terminally and pendently Si—H-functionalized polydimethylsiloxane (e=166, g=10, R⁵═H) of the general formula HMe₂SiO(SiMeHO)₁₀(SiMe₂O)₁₆₆SiMe₂H (SiH value: 0.081%) are added dropwise over the course of 15 minutes. When addition is at an end, and after cooling, the conversion, according to the SiH value method, was 100%.

Distillative removal of the volatile compounds gives a colorless, clear liquid.

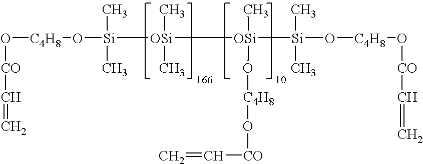

### Example 4

Reaction of a pendent Si—H-functional siloxane (e=28, g=2, R⁵=Me) with a monoacrylated polyether (Bisomer PEA 6) using a boron catalyst:

23 g of Bisomer PEA 6 are heated to 110° C. in an inert atmosphere in a four-necked flask equipped with stirrer, high-efficiency reflux condenser, thermometer and dropping funnel together with 0.034 g of tris(pentafluorophenyl)borane catalyst and 500 ppm of methylhydroquinone. When the temperature has been reached, 78.7 g of pendently Si—H-functionalized polydimethylsiloxane (e=28, g=2, R⁵=Me) of the general formula Me₃SiO(SiMeH)₂(SiMe₂O)₂₈SiMe₃ (SiH value: 0.0854%) are added dropwise over the course of 15 minutes. When addition is at an end, and after cooling, the conversion, according to the SiH value method, was 100%.

Filtration using 1% of Harbolite filter aid and subsequent distillative removal of the volatile compounds give a water-clear, colorless liquid.

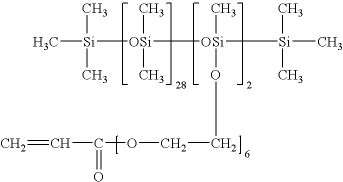

### Example 5

Reaction of a pendent Si—H-functional siloxane (e=27, g=3, R⁵=Me) with a monoacrylated polyether (Bisomer PEA 6) using a boron catalyst:

60.4 g of Bisomer PEA 6 are heated to 110° C. in an inert atmosphere in a four-necked flask equipped with stirrer, high-efficiency reflux condenser, thermometer and dropping funnel together with 0.09 g of tris(pentafluorophenyl)borane catalyst and 500 ppm of methylhydroquinone. When the temperature has been reached, 138.2 g of pendently Si—H-functionalized polydimethylsiloxane (e=27, g=3, R⁵=Me) of the general formula Me₃SiO(SiMeH)₃(SiMe₂O)₂₇SiMe₃ (SiH value: 0.128%) are added dropwise over the course of 15 minutes. When addition is at an end, and after cooling, the conversion, according to the SiH value method, was 100%.

Filtration using 1% of Harbolite filter aid and subsequent distillative removal of the volatile compounds give a water-clear, colorless liquid.

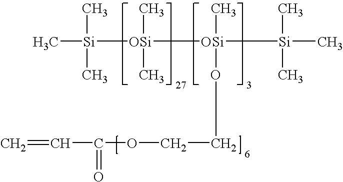

### Example 6

Reaction of a pendent Si—H-functional siloxane (e=26, g=4, R⁵=Me) with a monoacrylated polyether (Bisomer PEA 6) using a boron catalyst:

75 g of Bisomer PEA 6 are heated to 110° C. in an inert atmosphere in a four-necked flask equipped with stirrer, high-efficiency reflux condenser, thermometer and dropping funnel together with 0.11 g of tris(pentafluorophenyl)borane catalyst and 500 ppm of methylhydroquinone. When the temperature has been reached, 126.7 g of pendently Si—H-functionalized polydimethylsiloxane (e=26, g=4, R⁵=Me) of the general formula Me₃SiO(SiMeH)₄(SiMe₂O)₂₆SiMe₃ (SiH value: 0.173%) are added dropwise over the course of 15 minutes. When addition is at an end, and after cooling, the conversion, according to the SiH value method, was 100%.

Filtration using 1% of Harbolite filter aid and subsequent distillative removal of the volatile compounds give a water-clear, colorless liquid.

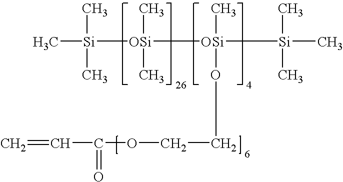

### Example 7

Reaction of a pendent Si—H-functional siloxane (e=25, g=5, R⁵=Me) with a monoacrylated polyether (Bisomer PEA 6) using a boron catalyst:

86.1 g of Bisomer PEA 6 are heated to 110° C. in an inert atmosphere in a four-necked flask equipped with stirrer, high-efficiency reflux condenser, thermometer and dropping funnel together with 0.128 g of tris(pentafluorophenyl)borane catalyst and 500 ppm of methylhydroquinone. When the temperature has been reached, 114.7 g of pendently Si—H-functionalized polydimethylsiloxane (e=25, g=5, R⁵=Me) of the general formula Me₃SiO(SiMeH)₅(SiMe₂O)₂₅SiMe₃ (SiH value: 0.22%) are added dropwise over the course of 15 minutes. When addition is at an end, and after cooling, the conversion, according to the SiH value method, was 100%.

Filtration using 1% of Harbolite filter aid and subsequent distillative removal of the volatile compounds give a water-clear, colorless liquid.

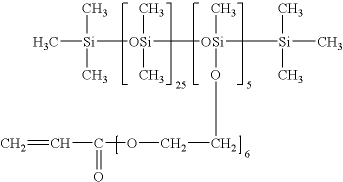

### Example 8

Reaction of a pendent Si—H-functional siloxane (e=13, g=5, R⁵=Me) with a monoacrylated polyether (Bisomer PEA 6) using a boron catalyst:

32.6 g of Bisomer PEA 6 are heated to 110° C. in an inert atmosphere in a four-necked flask equipped with stirrer, high-efficiency reflux condenser, thermometer and dropping funnel together with 0.038 g of tris(pentafluorophenyl)borane catalyst and 500 ppm of methylhydroquinone. When the temperature has been reached, 28.6 g of pendently Si—H-functionalized polydimethylsiloxane (e=13, g=5, R⁵=Me) of the general formula Me₃SiO(SiMeH)₅(SiMe₂O)₁₃SiMe₃ (SiH value: 0.353%) are added dropwise over the course of 15 minutes. When addition is at an end, and after cooling, the conversion, according to the SiH value method, was 100%.

Filtration using 1% of Harbolite filter aid and subsequent distillative removal of the volatile compounds give a water-clear, colorless liquid.

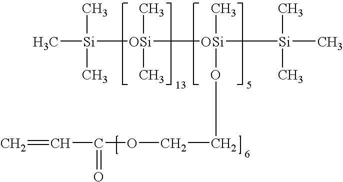

### Example 9

Reaction of a terminal Si—H-functional siloxane (e=18, R⁵═H) with a monoacrylated dicaprolactone (Sartomer SR 495) using a boron catalyst:

34.2 g of Sartomer SR 495 are heated to 110° C. in an inert atmosphere in a four-necked flask equipped with stirrer, high-efficiency reflux condenser, thermometer and dropping funnel together with 0.038 g of tris(pentafluorophenyl)borane catalyst and 500 ppm of methylhydroquinone. When the temperature has been reached, 71.5 g of terminally Si—H-functionalized polydimethylsiloxane (e=18, R⁵═H) of the general formula HMe₂Si(SiMe₂O)₁₈SiMe₂H (SiH value: 0.141%) are added dropwise over the course of 15 minutes. When addition is at an end, and after cooling, the conversion, according to the SiH value method, was 100%.

Distillative removal of the volatile compounds gives a water-clear, colorless liquid.

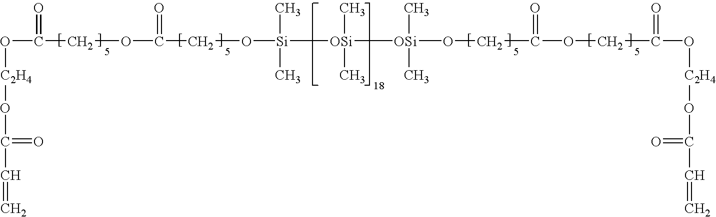

### Example 10

Reaction of a terminal Si—H-functional siloxane (e=18, R⁵═H) with 2-hydroxyethyl acrylate using a boron catalyst:

116.1 g of 2-hydroxyethyl acrylate are heated to 90° C. in an inert atmosphere in a four-necked flask equipped with stirrer, high-efficiency reflux condenser, thermometer and dropping funnel together with 0.512 g of tris(pentafluorophenyl)borane catalyst, 300 ppm of methylhydroquinone and 526.6 g of toluene. When the temperature has been reached, 725.1 g of terminally Si—H-functionalized polydimethylsiloxane (e=18, R⁵═H) of the general formula HMe₂SiO(SiMe₂O)₁₈SiMe₂H (SiH value: 0.139%) are added dropwise over the course of 15 minutes. When addition is at an end, and after cooling, the conversion, according to the SiH value method, was 100%.

Distillative removal of the volatile compounds gives a water-clear, colorless liquid.

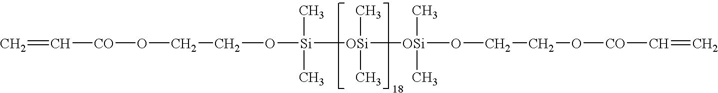

### Example 11

Reaction of a terminal Si—H-functional siloxane (e=18, R⁵═H) with an acrylated polyether (Bisomer PEA 6) using a boron catalyst:

328.1 g of Bisomer PEA 6 are heated to 90° C. in an inert atmosphere in a four-necked flask equipped with stirrer, high-efficiency reflux condenser, thermometer and dropping funnel together with 0.512 g of tris(pentafluorophenyl)borane catalyst, 500 ppm of methylhydroquinone, 500 ppm of phenothiazine and 526.6 g of toluene. When the temperature has been reached, 725.1 g of terminally Si—H-functionalized polydimethylsiloxane (e=18, R⁵═H) of the general formula HMe₂SiO(SiMe₂O)₁₈SiMe₂H (SiH value: 0.139%) are added dropwise over the course of 15 minutes. When addition is at an end, and after cooling, the conversion, according to the SiH value method, was 100%.

Distillative removal of the volatile compounds gives a water-clear, colorless liquid.

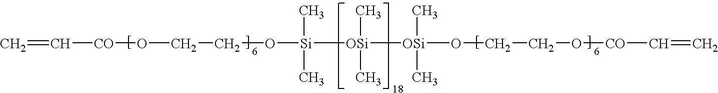

### Example 12

Reaction of a pendent Si—H-functional siloxane (e=95, g=15, R⁵=Me) with 2-hydroxyethyl acrylate using a boron catalyst:

88.8 g of 2-hydroxyethyl acrylate are heated to 90° C. in an inert atmosphere in a four-necked flask equipped with stirrer, high-efficiency reflux condenser, thermometer and dropping funnel together with 0.15 g of tris(pentafluorophenyl)borane catalyst, 300 ppm of methylhydroquinone and 83.6 g of toluene.

When the temperature has been reached, 329.4 g of pendently Si—H-functionalized polydimethylsiloxane (e=95, g=15, R⁵=Me) of the general formula Me₃SiO(SiMeHO)₁₅(SiMe₂O)₉₅SiMe₃ (SiH value: 0.18%) are added dropwise over the course of 25 minutes. When addition is at an end, and after cooling, the conversion, according to the SiH value method, was 100%.

Distillative removal of the volatile compounds gives a colorless, slightly turbid liquid.

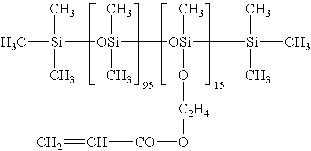

### Example 13

Reaction of a pendent Si—H-functional siloxane (e=160, g=10, R⁵=Me) with 2-hydroxyethyl acrylate using a boron catalyst:

87 g of 2-hydroxyethyl acrylate are heated to 90° C. in an inert atmosphere in a four-necked flask equipped with stirrer, high-efficiency reflux condenser, thermometer and dropping funnel together with 0.366 g of tris(pentafluorophenyl)borane catalyst, 300 ppm of methylhydroquinone and 200 g of toluene. When the temperature has been reached, 898 g of pendently Si—H-functionalized polydimethylsiloxane (e=160, g=10, R⁵=Me) of the general formula Me₃SiO(SiMeHO)₁₀(SiMe₂O)₁₆₀SiMe₃ (SiH value: 0.08%) are added dropwise over the course of 25 minutes. When addition is at an end, and after cooling, the conversion, according to the SiH value method, was 100%.

Distillative removal of the volatile compounds gives a colorless, clear liquid.

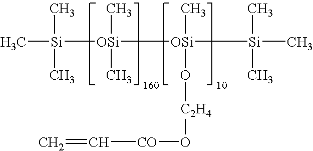

### Example 14

Reaction of a terminal and pendent Si—H-functional siloxane (e=190, g=35, R⁵═H) with 2-hydroxyethyl acrylate using a boron catalyst:

30.5 g of 2-hydroxyethyl acrylate are heated to 90° C. in an inert atmosphere in a four-necked flask equipped with stirrer, high-efficiency reflux condenser, thermometer and dropping funnel together with 0.128 g of tris(pentafluorophenyl)borane catalyst, 300 ppm of methylhydroquinone and 31 g of toluene. When the temperature has been reached, 124.8 g of terminally and pendently Si—H-functionalized polydimethylsiloxane (e=190, g=35, R⁵═H) of the general formula Me₂HSiO(SiMeHO)₃₅(SiMe₂O)₁₉₀SiHMe₂ (SiH value: 0.2%) are added dropwise over the course of 25 minutes. When addition is at an end, and after cooling, the conversion, according to the SiH value method, was 100%.

Distillative removal of the volatile compounds gives a colorless, slightly turbid liquid.

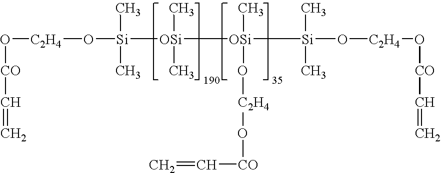

### Example 15

Reaction of a pendent Si—H-functional siloxane (e=87, g=18, R⁵=Me) with hydroxypropyl acrylate using a boron catalyst:

45.5 g of hydroxypropyl acrylate are heated to 90° C. in an inert atmosphere in a four-necked flask equipped with stirrer, high-efficiency reflux condenser, thermometer and dropping funnel together with 0.081 g of tris(pentafluorophenyl)borane catalyst, 300 ppm of methylhydroquinone and 60.7 g of toluene. When the temperature has been reached, 157 g of pendently Si—H-functionalized polydimethylsiloxane (e=87, g=18, R⁵=Me) of the general formula Me₃SiO(SiMeHO)₁₈(SiMe₂O)₈₇SiMe₃ (SiH value: 0.214%) are added dropwise over the course of 25 minutes. When addition is at an end, and after cooling, the conversion, according to the SiH value method, was 100%.

Distillative removal of the volatile compounds gives a colorless, clear liquid.

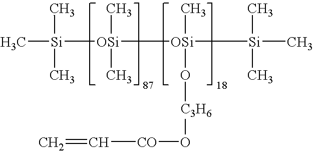

### Example 16

Reaction of a pendent Si—H-functional siloxane (e=11, g=7, R⁵=Me) with 2-hydroxyethyl acrylate using a boron catalyst:

40.6 g of 2-hydroxyethyl acrylate are heated to 110° C. in an inert atmosphere in a four-necked flask equipped with stirrer, high-efficiency reflux condenser, thermometer and dropping funnel together with 0.128 g of tris(pentafluorophenyl)borane catalyst and 300 ppm of methylhydroquinone. When the temperature has been reached, 67.7 g of pendently Si—H-functionalized polydimethylsiloxane (e=11, g=7, R⁵=Me) of the general formula Me₃SiO(SiMeHO)₇(SiMe₂O)₁₁SiMe₃ (SiH value: 0.31%) are added dropwise over the course of 25 minutes. When addition is at an end, and after cooling, the conversion, according to the SiH value method, was 100%.

Distillative removal of the volatile compounds gives a colorless, clear liquid.

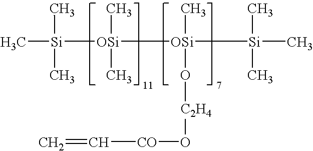

### Example 17

Reaction of a pendent Si—H-functional siloxane (e=13, g=5, R⁵=Me) with 2-hydroxyethyl acrylate using a boron catalyst:

24.4 g of 2-hydroxyethyl acrylate are heated to 110° C. in an inert atmosphere in a four-necked flask equipped with stirrer, high-efficiency reflux condenser, thermometer and dropping funnel together with 0.077 g of tris(pentafluorophenyl)borane catalyst and 300 ppm of methylhydroquinone. When the temperature has been reached, 57.1 g of pendently Si—H-functionalized polydimethylsiloxane (e=13, g=5, R⁵=Me) of the general formula Me₃SiO(SiMeHO)₅(SiMe₂O)₁₃SiMe₃ (SiH value: 0.353%) are added dropwise over the course of 25 minutes. When addition is at an end, and after cooling, the conversion, according to the SiH value method, was 100%.

Distillative removal of the volatile compounds gives a colorless, clear liquid.

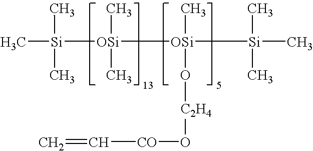

### Example 18

Reaction of a terminal Si—H-functional siloxane (e=7.2, R⁵═H) with a monoacrylated dicaprolactone (Sartomer SR 495) using a boron catalyst:

114 g of Sartomer SR 495 are heated to 90° C. in an inert atmosphere in a four-necked flask equipped with stirrer, high-efficiency reflux condenser, thermometer and dropping funnel together with 0.102 g of tris(pentafluorophenyl)borane catalyst, 113 g of toluene and 500 ppm of methylhydroquinone. When the temperature has been reached, 111 g of terminally Si—H-functionalized polydimethylsiloxane (e=7.2, R⁵═H) of the general formula HMe₂Si(SiMe₂O)_{7.2}SiMe₂H (SiH value: 0.302%) are added dropwise over the course of 15 minutes. When addition is at an end, and after cooling, the conversion, according to the SiH value method, was 100%.

Distillative removal of the volatile compounds gives a water-clear, colorless liquid.

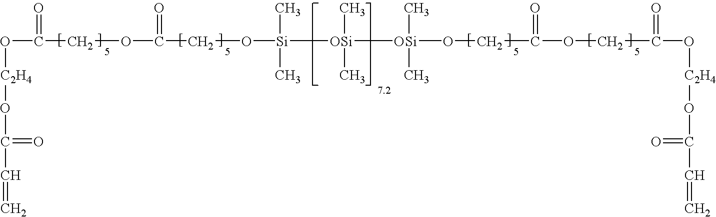

### Comparative Examples 19 and 20

Comparative example 19 is a commercial additive Tego Rad® 2100 from Tego Chemie Service GmbH. Comparative example 20 is a commercial additive Tego Rad® 2300 from Tego Chemie Service GmbH.

### Comparative Example 21

Reaction of a terminal Si—Cl-functional siloxane (N=20) with 2-hydroxyethyl acrylate using triethylamine:

23.2 g of 2-hydroxyethyl acrylate are heated to 90° C. in an inert atmosphere in a four-necked flask equipped with stirrer, high-efficiency reflux condenser, thermometer and dropping funnel together with 500 ppm of methylhydroquinone and 500 ppm of phenothiazine. When the temperature has been reached, 116 g of terminally Si—Cl-functionalized polydimethylsiloxane (e=18, R⁵═Cl) of the general formula ClMe₂SiO(SiMe₂O)₁₈SiMe₂Cl are added dropwise over the course of 30 minutes, and the HCl formed is stripped off by application of reduced pressure. After a reaction time of 1 h neutralization was carried out with triethylamine and the reaction product was diluted with toluene and filtered.

Distillative removal of the volatile compounds gives a pale yellow liquid.

After 14 days' storage the product, previously clear, displays turbidity. An irritating odor due to triethylamine residues is perceptible.

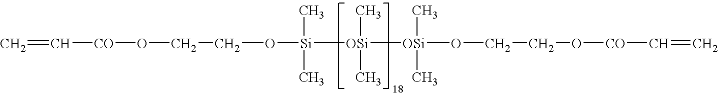

### Comparative Example 22

Reaction of a terminal Si—Cl-functional siloxane (N=20) with an acrylated polyether (Bisomer PEA 6) using triethylamine:

53.2 g of Bisomer PEA 6 are heated to 90° C. in an inert atmosphere in a four-necked flask equipped with stirrer, high-efficiency reflux condenser, thermometer and dropping funnel together with 500 ppm of methylhydroquinone and 500 ppm of phenothiazine. When the temperature has been reached, 116 g of terminally Si—Cl-functionalized polydimethylsiloxane (e=18, R⁵═Cl) of the general formula ClMe₂SiO(SiMe₂O)₁₈SiMe₂Cl are added dropwise over the course of 30 minutes, and the HCl formed is stripped off by application of reduced pressure. After a reaction time of 1 h neutralization was carried out with triethylamine and the reaction product was diluted with toluene and filtered. Distillative removal of the volatile compounds gives a pale yellow liquid.

After 14 days' storage the product, previously clear, displays turbidity. An irritating odor due to triethylamine residues is perceptible.

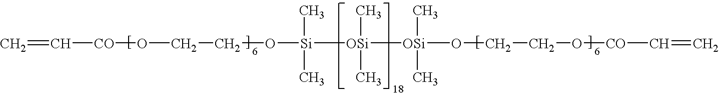

### Example 23

Reaction of a terminal Si—H-functional siloxane (e=98, R⁵═H) with pentaerythritol triacrylate (PETTriA) using a boron catalyst:

99.5 g of pentaerythritol triacrylate are heated to 90° C. in an inert atmosphere in a four-necked flask equipped with stirrer, high-efficiency reflux condenser, thermometer and dropping funnel together with 0.085 g of tris(pentafluorophenyl)borane catalyst, 616.5 g of toluene and 500 ppm of methylhydroquinone. When the temperature has been reached, 616.5 g of terminally Si—H-functionalized polydimethylsiloxane (e=98, R⁵═H) of the general formula HMe₂SiO(SiMe₂O)₉₈SiMe₂H (SiH value: 0.0272%) are added dropwise over the course of 30 minutes. When addition is at an end, and after cooling, the conversion, according to the SiH value method, was 100%.

Distillative removal of the volatile compounds gives a colorless liquid.

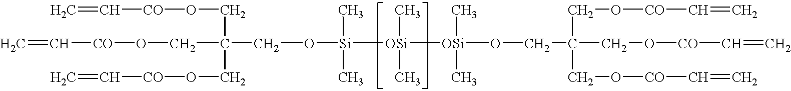

Shown below are the performance properties of a variety of compounds for use in accordance with the invention, in comparison to noninventive compounds.

Compounds tested for use in accordance with the invention were compounds 1 to 18 and 23.

Noninventive compounds used, according to the state of the art, were the following additives:

Commercial additives: compound 19: Tego Rad® 2100 (Tego Chemie Service GmbH) and compound 20: Tego Rad® 2300 (Tego Chemie Service GmbH). Both compounds were prepared via an Si—C linkage.

Si—O—C-linked compounds prepared via SiCl chemistry are also used, as compound 21 and compound 22.

For investigating the performance properties the following printing ink formulas are selected (amounts in percent by weight):

Formula 1:

| | | |
|---|---|---|
| Ebecryl ® 6054 | 4.2 parts | aromatic polyether acrylate, |
| | | UCB |
| Lauromer ® TPGDA | 45.3 parts | tripropylene glycol diacrylate, |
| | | BASF |
| Benzophenone | 5.0 parts | benzophenone, Merck |
| Ebecryl ® P115 | 5.0 parts | amine-functional acrylate, UCB |
| Additive | 0.5 part | |
| According to the invention | | |

Formula 2:

| | | |
|---|---|---|
| Laromer ® PO84 F | 94.5 parts | polyether acrylate, BASF |
| Darocure ® 1173 | 3.0 parts | photoinitiator, Merck |
| Ebecryl ® P 115 | 2.0 parts | amine-functional acrylate, UCB |
| Additive | 0.5 part | |
| According to the invention | | |

The printing inks are formulated in conventional manner in accordance with the formulas above. The last formula ingredient added in each case is the additives, with incorporation taking place by means of a bead mill disc at 2500 rpm for one minute.

The printing inks are knife-coated at 12 μm wet onto corona-pretreated PVC film. Curing takes place by exposure to ultraviolet light (UV) at 120 W/cm with belt speeds of 20 m/min. This operation is repeated once in each case. The release forces are determined using a 25 mm wide adhesive tape from tesa AG which has been coated with rubber adhesive and is available commercially under the name Tesa® 4154. To measure the abhesiveness this adhesive tape is rolled on at 70 g/cm² 5 minutes and, respectively, 24 hours after the printing ink has cured. After three hours' storage at room temperature a measurement is made of the force required to remove the respective adhesive tape from the substrate at a speed of 12 mm/s and a peel angle of 180°. This force is termed the release force.

Scratch resistance is the resistance of a surface to visible damage in the form of lines, caused by hard moving bodies in contact with the surface. So-called scratch values are measured using a specially converted electrically driven film applicator. The inserted doctor blade is replaced on the movable blade mount by a plate which lies on rollers at the other end of the applicator. By means of the blade mount it is possible to move the plate, to which the substrate (film coated with printing ink) is fixed. In order to simulate scratching stress, a block with three points is placed on the printing ink film and weighted with 500 g. The test sheet on the plate is pulled away beneath the weight at a speed of 12 mm/s. The vertical force required to do this is measured and designated as the scratch value. The scratch values are each determined 24 hours after the inks have cured.

If the pointed block is replaced by a block with a flat felt underlay, and the procedure described above is repeated, then the frictional force measured is the friction coefficient. These tests also each take place 24 hours after the inks have cured.

Tables 1 and 2 show average values for 5 individual measurements.

TABLE 1
(Formula 1):

| | | | | Release | |
|---|---|---|---|---|---|
| | | | | force | Release |
| | | Friction | Scratch | after 5 | force after |
| | Conc. in % | coefficient | value | min | 24 h |
| Compound | by weight | [cN] | [cN] | [cN] | [cN] |
| Blank | — | 342 | 77 | 912 | 903 |
| 1 | 0.5 | 57 | 18 | 67 | 63 |
| 2 | 0.5 | 53 | 16 | 19 | 16 |
| 3 | 0.5 | 61 | 27 | 36 | 32 |
| 4 | 0.5 | 58 | 19 | 198 | 192 |
| 5 | 0.5 | 65 | 20 | 291 | 275 |
| 6 | 0.5 | 73 | 33 | 357 | 341 |
| 7 | 0.5 | 80 | 18 | 441 | 437 |
| 8 | 0.5 | 125 | 40 | 703 | 700 |
| 9 | 0.5 | 44 | 19 | 371 | 366 |
| 10 | 0.5 | 76 | 17 | 459 | 457 |
| 11 | 0.5 | 58 | 18 | 519 | 516 |
| 12 | 0.5 | 41 | 13 | 210 | 215 |
| 13 | 0.5 | 36 | 18 | 35 | 37 |
| 14 | 0.5 | 52 | 26 | 214 | 221 |
| 15 | 0.5 | 43 | 14 | 175 | 189 |
| 16 | 0.5 | 102 | 39 | 671 | 690 |
| 17 | 0.5 | 92 | 23 | 683 | 703 |
| 18 | 0.5 | 56 | 21 | 700 | 715 |
| 19 | 0.5 | 261 | 69 | 731 | 733 |
| 20 | 0.5 | 187 | 43 | 687 | 693 |
| 21 | 0.5 | 82 | 23 | 532 | 521 |
| 22 | 0.5 | 67 | 27 | 547 | 549 |
| 23 | 0.5 | 18 | 15 | 35 | 34 |

TABLE 2
(Formula 2):

| | | | | Release | |
|---|---|---|---|---|---|
| | | | | force | Release |
| | | Friction | Scratch | after 5 | force after |
| | Conc. in % | coefficient | value | min | 24 h |
| Compound | by weight | [cN] | [cN] | [cN] | [cN] |
| Blank | — | 312 | 121 | 836 | 814 |
| 1 | 0.5 | 67 | 20 | 41 | 38 |
| 2 | 0.5 | 59 | 13 | 15 | 13 |
| 3 | 0.5 | 71 | 17 | 25 | 23 |
| 4 | 0.5 | 68 | 26 | 330 | 328 |
| 5 | 0.5 | 82 | 27 | 273 | 272 |
| 6 | 0.5 | 83 | 39 | 309 | 299 |
| 7 | 0.5 | 86 | 36 | 427 | 396 |
| 8 | 0.5 | 129 | 51 | 613 | 592 |
| 9 | 0.5 | 59 | 28 | 473 | 458 |
| 10 | 0.5 | 78 | 16 | 592 | 572 |
| 11 | 0.5 | 65 | 20 | 650 | 645 |
| 12 | 0.5 | 48 | 22 | 241 | 238 |
| 13 | 0.5 | 42 | 18 | 59 | 48 |
| 14 | 0.5 | 53 | 29 | 241 | 263 |
| 15 | 0.5 | 46 | 22 | 200 | 209 |
| 16 | 0.5 | 125 | 42 | 674 | 698 |
| 17 | 0.5 | 107 | 31 | 701 | 705 |
| 18 | 0.5 | 63 | 27 | 704 | 721 |
| 19 | 0.5 | 263 | 102 | 770 | 773 |
| 20 | 0.5 | 195 | 96 | 732 | 740 |
| 21 | 0.5 | 86 | 22 | 613 | 621 |
| 22 | 0.5 | 69 | 26 | 672 | 677 |
| 23 | 0.5 | 20 | 16 | 37 | 33 |

Tables 1 and 2 show that the inventive examples 1 to 18 and 23, as additives in both coating formulas, have lower friction coefficients, scratch values and release forces than the comparison sample without additive (blank value) and the commercial compounds 19 and 20.

In the case of the noninventive compounds 21 and 22 the Si—O—C bonds were produced by reacting chlorosiloxanes with primary alcohols. The inventive compounds 10 and 11 represent systems having the same structure as the compounds 21 and 22, but produced by dehydrogenative coupling.

Tables 1 and 2 show that the inventive examples 10 and 11, as additives in both coating formulas, surprisingly have lower friction coefficients, scratch values and release forces than the comparison sample of the noninventive compounds 21 and 22.

The higher values for the noninventive compounds 21 and 22 as compared with the inventive compounds 10 and 11 point to acid residues or to a salt load which cannot be fully removed from the reaction mixture. Moreover, after storage, the noninventive compounds 21 and 22 have a certain turbidity and amine odor, which customers do not want.

Having thus described in detail various embodiments of the present invention, it is to be understood that the invention defined by the above paragraphs is not to be limited to particular details set forth in the above description as many apparent variations thereof are possible without departing from the spirit or scope of the present invention.

1. A method of coating a substrate which comprises coating the substrate with a radiation-curable coating with an additive comprising an organopolysiloxanyl (meth)acrylate compound obtainable by reacting polysiloxanes containing SiH groups, of the general average formula (II) 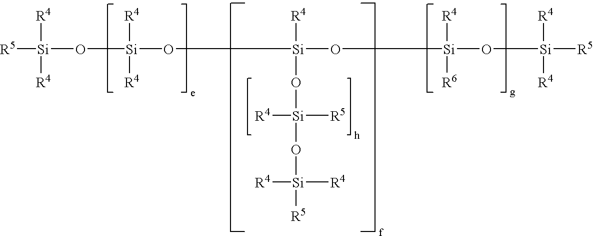
in which
R⁴ radicals are identical or different and selected from the group consisting of linear and branched, saturated, mono- and polyunsaturated alkyl, aryl, alkaryl and aralkyl radicals wherein the alkyl has 1 to 20 carbon atoms, alkyl radical having 1 to 5 carbon atoms, and a methyl radical,
R⁵ is H or R⁴,
R⁶ is H,
e is a range selected from the group consisting of 0 to 1000, 5 to 500, 10 to 300, and 10 to 200,
f is a range selected from the group consisting of 0 to 5, and <2,
g is a range selected from the group consisting of 0 to 200, 0 to 100, 0 to 80, and 0 to 50,
h is a range selected from the group consisting of 0 to 1000, 0 to 500, 0 to 300, and <100,
at least one radical R⁵ or R⁶ necessarily being H,
with an alcohol selected from the group consisting of singly and multiply (meth)acrylated monoalcohols and polyalcohols, a mixture of singly and multiply (meth)acrylated monoalcohols and polyalcohols thereof, mixtures of singly or multiply (meth)acrylated monoalcohols or polyalcohols with at least one other alcohol selected from the group consisting of linear and branched, saturated, mono- and polyunsaturated, aromatic, aliphatic-aromatic monoalcohols and polyalcohols, polyether monoalcohols, polyether polyalcohols, polyester monoalcohols, polyester polyalcohols, amino alcohols, especially N-alkylamino- and arylamino-EO and —PO alcohols, N-alkylamino and arylamino alcohols, and mixtures thereof, which comprises replacing some or all of the existing SiH groups of the polysiloxane in one or more process steps, using a Lewis-acidic catalyst or a catalyst composed of a carboxylic acid and salts of carboxylic acids, by alkoxide radicals of the alcohols employed,
wherein the additive is in an amount of about 0.01% to about 10% by weight, in the radiation-curing coating.

2. The method of claim 1, wherein e is from 10 to 200, f is <2, g is from 0 to 50 and h is <100.

3. The method of claim 2, wherein when g>0, then e+g is in the range of 20 to 250.

4. The method of claim 1, wherein the additive is in an amount of about 0.1% to about 1% in the radiation-curing coating.

5. The method of claim 1, wherein the coating of a substrate results in a coated substrate with at least one of the following properties:
(1) a friction coefficient of about 15 cN to about 60 cN;
(2) a scratch value of about 10 cN to about 20 cN;
(3) a release force after 5 minutes of curing of about 10 cN to about 500 cN;
(4) a release force after 24 hours of curing of about 10 cN to about 500 cN.

6. The method of claim 1, wherein the coating is substantially-free of turbidity and amine odor.

7. A coated substrate produced by the process of claim 1.

8. A method of coating a substrate which comprises coating the substrate with a radiation-curable coating with an additive comprising an organopolysiloxane compound having groups which carry (meth)acrylic esters attached pendently and terminally or only pendently, via SiOC groups, of the general average formula (I) 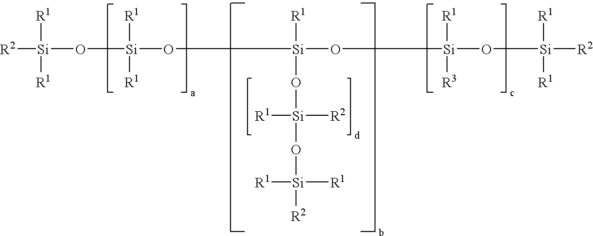
in which
R¹ radicals are identical or different and selected from the group consisting of linear and branched, saturated, mono- and polyunsaturated alkyl, aryl, alkaryl and aralkyl radicals wherein the alkyl has 1 to 20 carbon atoms,
R² radicals are identical or different radicals R¹ or R³,
R³ radicals are identical or different, selected from the group consisting of singly or multiply (meth)acrylated monoalkoxylates or (meth)acrylated polyalkoxylates, a mixture of singly or multiply (meth)acrylated monoalkoxylates or (meth)acrylated polyalkoxylates thereof, a mixture of the singly or multiply (meth)acrylated monoalkoxylates or polyalkoxylates with at least one other alkoxylate, selected from the group consisting of linear or branched, saturated, monounsaturated or polyunsaturated, aromatic, aliphatic-aromatic monoalcohols or polyalcohols, polyether monoalcohols, polyether polyalcohols, polyester monoalcohols, polyester polyalcohols, amino alcohols, especially N-alkylamino- and arylamino-ethylene oxide- and -propylene oxide-alcohols, N-alkylamino or arylamino alkoxylates and mixtures thereof,
the ratio of the singly or multiply (meth)acrylated monoalkoxylates or polyalkoxylates to the other alkoxylates being chosen such that at least one singly or multiply (meth)acrylated monoalkoxylate or polyalkoxylate radical is present in the organopolysiloxane,
a is a range selected from the group consisting of 0 to 1000, 5 to 500, and 10 to 300,
b is a range selected from the group consisting of 0 to 5 and <2,
c is a range selected from the group consisting of 1 to 2001 to 100 and1 to 80,
d is a range selected from the group consisting of 0 to 1000, 0 to 500, 0 to 300, and 0 to 100,
at least one of the radicals R² or R³ being a (meth)acrylated monoalkoxylate or polyalkoxylate radical,
in amounts of about 0.01% to about 10% by weight, as additives in radiation-curing coatings.

9. The method of claim 8, wherein a is 10 to 200.

10. The method of claim 8, wherein c=1 to 50.

11. The method of claim 8, wherein e+g is from 10 to 250.

12. The method of claim 8, wherein R¹ is an alkyl radical selected from the group consisting of an alkyl radical having 1 to 5 carbon atoms and a methyl radical.

13. The method of claim 8, wherein R³ is at least one radical selected from the group consisting of 2-hydroxyethyl acrylate, hydroxypropyl acrylate, hydroxybutyl acrylate and pentaerythritol acrylate.

14. The method of claim 8, wherein R³ is at least one radical selected from the group consisting of monoacrylated polyethers and monoacrylated di- and polycaprolactones.

15. The method of claim 8, wherein the additive is in an amount of about 0.1% to about 1% in the radiation-curing coating.

16. The method of claim 8, wherein the coating of a substrate results in a coated substrate with at least one of the following properties:
(1) a friction coefficient of about 15 cN to about 60 cN;
(2) a scratch value of about 10 cN to about 20 cN;
(3) a release force after 5 minutes of curing of about 10 cN to about 500 cN;
(4) a release force after 24 hours of curing of about 10 cN to about 500 cN.

17. The method of claim 8, wherein the coating is substantially-free of turbidity and amine odor.

18. A coated substrate produced by the process of claim 8.
